(19) United States
(12) Patent Application Publication
(10) Pub. No.: US 2002/0009010 A1
(43) Pub. Date: Jan. 24, 2002

(54) DYNAMIC RANDOM ACCESS MEMORY

(76) Inventor: GORO HAYAKAWA, TOKYO (JP)

Correspondence Address: MCDERMOTT WILL & EMERY, 600 13TH STREET, N.W., WASHINGTON, DC, 20005-3096, US

(21) Appl. No.: 09/413,819

(22) Filed: Oct. 7, 1999

(30) Foreign Application Priority Data
Jan. 28, 1999 (JP) 11-020127

(51) Int. Cl. G11C 7/00

(52) U.S. Cl. 365/222; 365/193

(57) ABSTRACT

A DRAM includes a control circuit for stopping an operation of increasing a potential of a Vpp line by a first pump under a self refresh mode.

### TECHNICAL FIELD

The present invention relates to a dynamic random access memory (hereinafter referred to as DRAM) and, more particularly, to control of a Vpp generator at the time of self refresh mode.

### BACKGROUND ART

As the DRAM is a volatile memory, to keep data, it is necessary to refresh memory cells within a certain period. As one of the refreshing methods, there is a self refresh mode. In this self refresh mode, a RAS signal and a CAS signal are respectively changed from “H” level to “L” level at the timing of CBR (CAS Before RAS). During the period when these two signals are at “L” level, word lines are selected one after another by a row address signal on the basis of an internal RAS signal generated in the DRAM, thus memory cells connected to the selected word lines are refreshed.

FIG. 6 is a diagram showing an arrangement of a DRAM according to a prior art. In the drawing, reference numeral 1 indicates a RAS buffer which receives a RAS signal (EXTZRAS signal) and generates an internal RAS signal (ZRAS signal) synchronizing with the EXTZRAS signal; numeral 2 indicates a CAS buffer which receives a CAS signal (EXTZCAS signal) and generates an internal CAS signal (ZCAS signal) synchronizing with the EXTZCAS signal; numeral 3 indicates a WE buffer which receives a write enable signal (EXTZWE signal) and generates a control signal used for a writing operation; numeral 4 is a row address buffer which receives an address signal for selecting a word line synchronously with the ZRAS signal; numeral 5 is a row decoder which decodes the address signal from the row address buffer 4; numeral 6 is a word driver which drives a word line (WL) on the basis of the result decoded by the row decoder 5; numeral 7 is a column address buffer which receives an EXTADD signal synchronously with the ZCAS signal from the CAS buffer 2; numeral 8 is a column decoder which decodes the EXTADD signal from the column address buffer 7 and selects a bit line (BL); numeral 9 is a memory cell array; numeral 10 is a sense amplifier; numeral 11 is an I/O circuit which controls input and output of data to and from the memory cell array 9; numeral 12 is an internal address generator which generates an address signal for selecting a word line on the basis of the ZRAS signal at the time of self refresh mode; a numeral 13 is a self refresh switching circuit which detects that the normal mode has been switched to the self refresh mode on the basis of the ZRAS signal and the ZCAS signal and generates a control signal (ZBBU signal) ; numeral 14 is a self refresh ring oscillator which generates a ZREFS signal for changing the period of the ZRAS signal on the basis of the ZBBU signal and outputs the ZREFS signal to the RAS buffer 1; and numeral 15 is a Vpp generator which monitors a potential of a Vpp line connected to the word driver 6 for driving the word line and keeps the potential at Vpp. The Vpp being a potential for driving the word line shows a higher potential (not lower than Vcc+Vth) than the power source potential Vcc of the DRAM. Reference mark MC indicates a memory cell. At the time of normal mode, the EXTADD signal is inputted to the row address buffer 4, and at the time of self refresh mode, an address signal generated in the internal address generator 12 is inputted to the row address buffer 4. The Vpp being a potential of the Vpp line is supplied to the word driver 6.

FIG. 7 is a diagram showing an arrangement of the Vpp generator 15 in FIG. 6. In the drawing, reference numeral 16 indicates an active detector, numeral 17 indicates an active pump, numeral 18 is a stand-by detector, and numeral 19 is a stand-by pump. The active detector 16 and the active pump 17 are operated synchronously with the ZRAS signal. The stand-by detector 18 and the stand-by pump 19 are operated asynchronously with the ZRAS signal. The active detector 16 and the stand-by detector 18 monitor the potential of the Vpp line. When a potential of the Vpp line is lower than the preset detection level, the active pump 17 and the stand-by pump 19 receive results of monitor (ENACT signal, ENSTB signal) respectively from the active detector 16 and the stand-by detector 18, and increase the potential of the Vpp line to Vpp. The active detector 16 monitors the potential of the Vpp line during a certain period after the ZRAS signal has been changed from H level to L level, while the stand-by detector 18 monitors the potential of the Vpp line at all times. The stand-by pump 19 has a certain pumping capacity (supply capacity of current to the Vpp line) without being influenced by the period of the ZRAS signal.

Generally, in the DRAM of 4 Mbits or more, the Vpp generator 15 is not only provided with a pump for increasing the potential of the Vpp line like the Vpp generator employed in the 1 Mbit DRAM. To restrain the application of an excessively high voltage to a gate oxide film of the transistor in memory cell and to cope with the voltage increase of bit line in the shared sense amplifier system, the Vpp generator 15 is also provided with two detectors comprising the active detector 16 and the stand-by detector 18 and with two pumps comprising the active pump 17 and the stand-by pump 19, as shown in FIG. 7.

FIG. 8 is a timing chart to explain the operation of the Vpp generator 15. Each circuit has a delay, and the output signal is outputted with a delay from the input signal.

First, at the time of normal mode (including stand-by time) in which reading and writing operations are performed, synchronously with the last transition of the EXTZRAS signal from H level to L level, the ZRAS signal is also changed from H level to L level. During a certain period after the ZRAS signal has been changed from H level to L level, the active detector 16 monitors the potential of the Vpp line, and when the potential is lower than the detection level, an ENACT signal (H level) is generated and outputted to the active pump 17. The active pump 17 having received the ENACT signal of H level increases the potential of the Vpp line to Vpp. The active detector 16 is not operated (in non active state) at any time other than a certain period after the ZRAS signal has been changed from H level to L level. But, when the potential of the Vpp line is lower than the detection level, irrespective of the level of the ZRAS signal, an ENSTB signal (H level) is generated by the stand-by detector 18 monitoring the Vpp line at all times, and the potential of the Vpp line is increased to Vpp by the stand-by pump 19. In conformity with the non active state of the active detector 16, the active pump 17 is not operated, either.

Then, at the time of self refresh mode, the period of the ZRAS signal becomes longer than that at the time of normal mode by the self refresh ring oscillator 14. For example, in the 64 Mbit DRAM, the period of the ZRAS signal is 84 ns to 16 μs at the time of normal mode, while it is about 30 μs at the time of self refresh mode. In the same manner as at the time of normal mode, the potential of the Vpp line is monitored by the active detector 16 and the stand-by detector 18, and increased to Vpp when required. The change of the ZBBU signal from H level to L level shows that the normal mode has been switched to the self refresh mode.

In FIG. 8, dot line portions of the Vpp line, the ENCT signal and the ENSTB signal indicate that the potential of the Vpp line is higher than the detection level and that it is not necessary to increase the potential of the Vpp line to Vpp. On the other hand, solid line portions indicate that the potential of the Vpp line is lower than the detection level and that the increase to Vpp is necessary.

However, in the conventional DRAM of above arrangement, the potential of the Vpp line is kept at Vpp by the Vpp generator having two detectors and two pumps at the time of both normal mode and self refresh mode, and for that purpose a large current consumption is required. For example, in the 64 Mbit DRAM, the current consumption by the Vpp generator mounts to about 30% of all current consumption, hence there is a problem that the current consumed by the Vpp generator must be reduced.

### DISCLOSURE OF THE INVENTION

Accordingly, the invention was made to solve the above-discussed problem and has an object of providing a DRAM in which current consumption of the Vpp generator is reduced.

This object and advantages are achieved by providing a novel and improved DRAM including a control circuit for stopping an operation of increasing a potential of a Vpp line by a first pump under a self refresh mode.

The above object and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF DRAWINGS

FIG. 1 is a diagram showing an arrangement of a DRAM according to the present invention.

FIG. 2 is a diagram showing an arrangement of a Vpp generator 20 and a control circuit 21 in FIG. 1.

FIG. 3 is a timing chart to explain the operation of the Vpp generator 20 and the control circuit 21.

FIG. 4 is a diagram showing an arrangement of an active detector 22 in FIG. 2.

FIG. 5 is a diagram showing an arrangement of an active pump 23 in FIG. 2.

FIG. 6 is a diagram showing an arrangement of a DRAM according to the prior art.

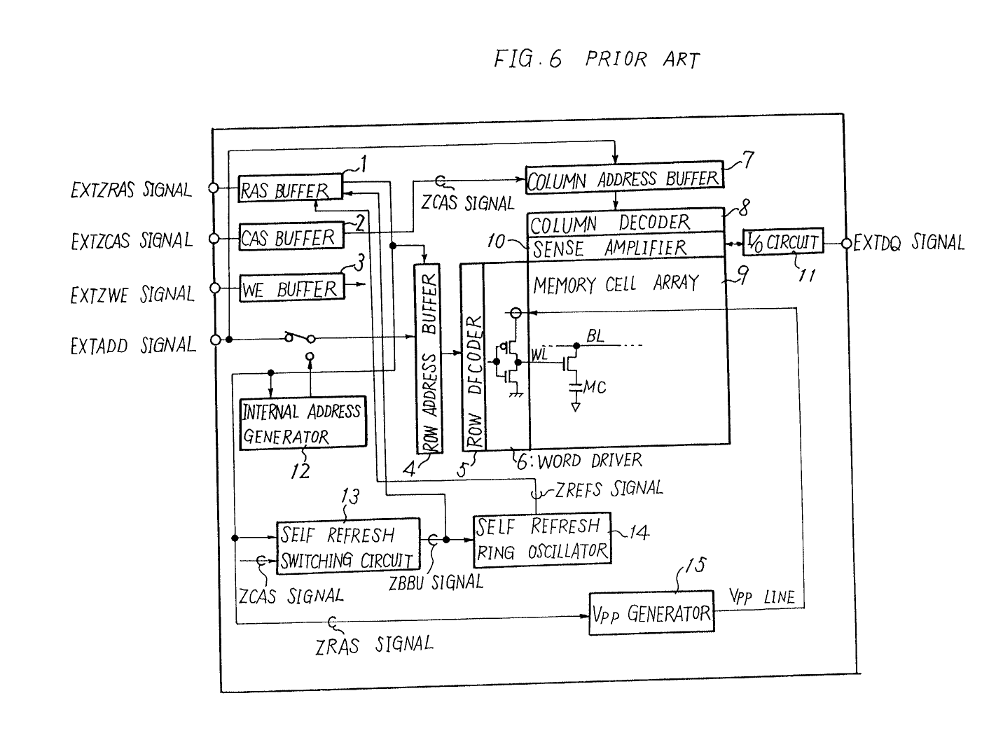

FIG. 7 is a diagram showing an arrangement of the Vpp generator 15 in FIG. 6.

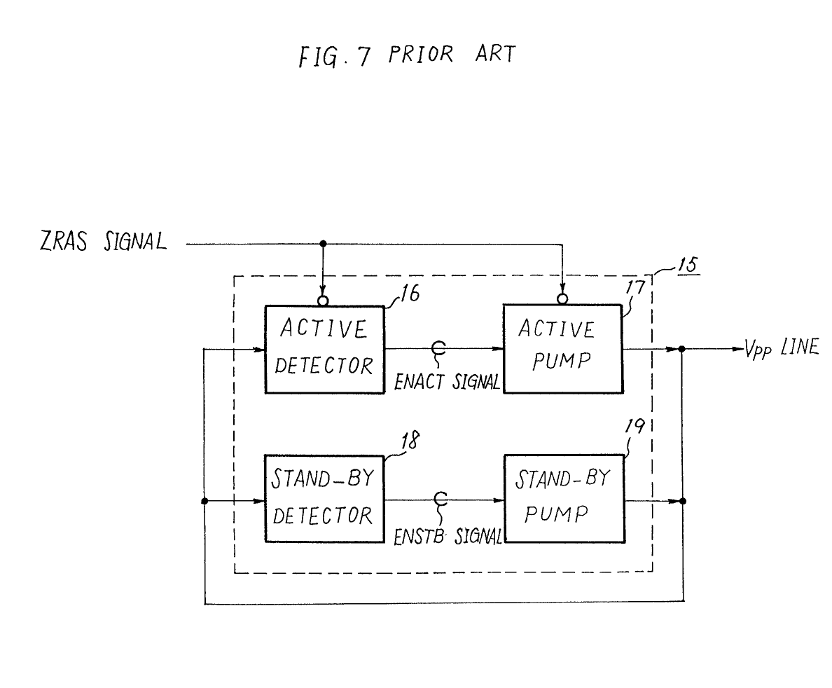

FIG. 8 is a timing chart to explain the operation of the Vpp generator 15.

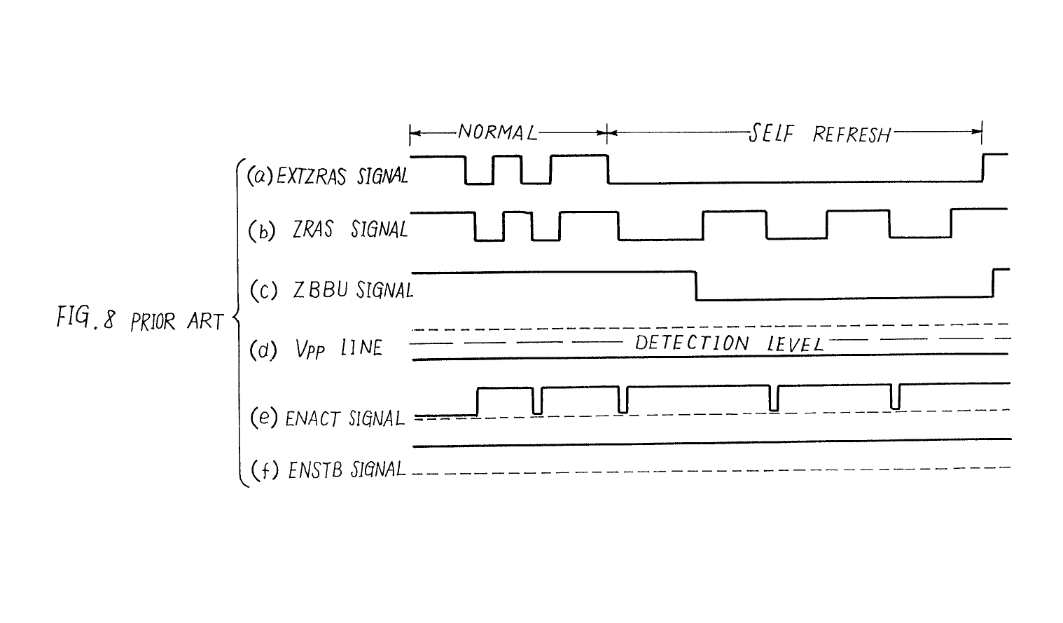

### BEST MODE FOR CARRYING OUT THE INVENTION

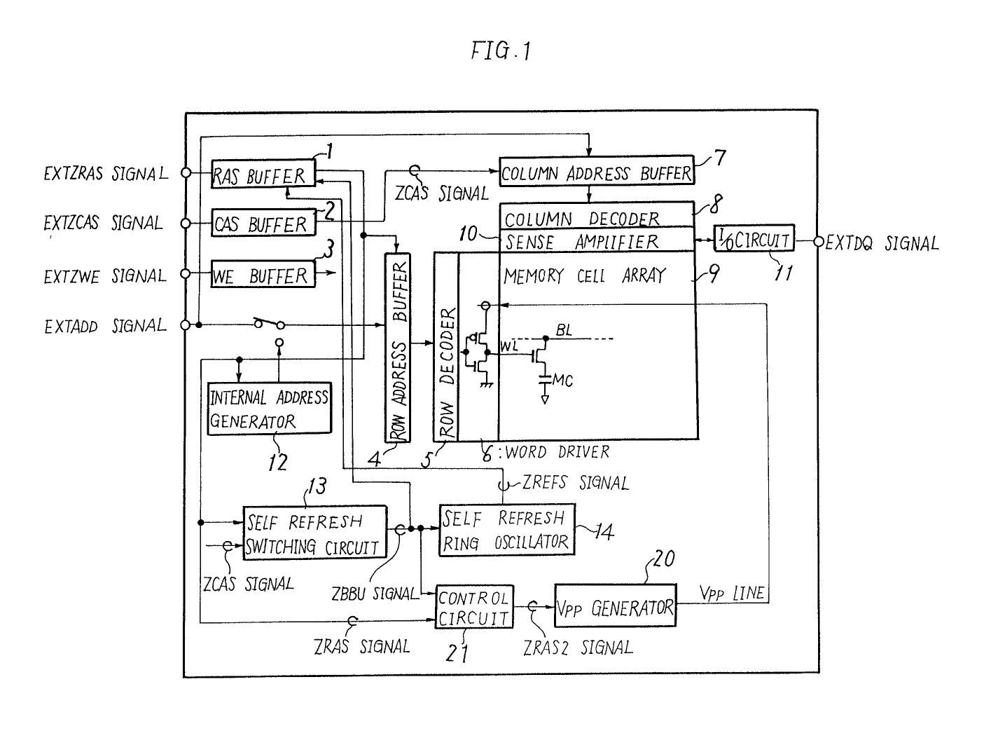

FIG. 1 is a diagram showing an arrangement of a DRAM according to the invention. In the drawing, reference numeral 1 indicates a RAS buffer which receives a RAS signal (EXTZRAS signal) and generates an internal RAS signal (ZRAS signal) synchronizing with the EXTZRAS signal; numeral 2 indicates a CAS buffer which receives a CAS signal (EXTZCAS signal) and generates an internal CAS signal (ZCAS signal) synchronizing with the EXTZCAS signal; numeral 3 indicates a WE buffer which receives a write enable signal (EXTZWE signal) and generates a control signal used for a writing operation; numeral 4 is a row address buffer which receives an address signal for selecting a word line synchronously with the ZRAS signal; numeral 5 is a row decoder which decodes the address signal from the row address buffer 4; numeral 6 is a word driver which drives a word line (WL) on the basis of the result decoded by the row decoder 5; numeral 7 is a column address buffer which receives an EXTADD signal synchronously with the ZCAS signal from the CAS buffer 2; numeral 8 is a column decoder which decodes the EXTADD signal from the column address buffer 7 and selects a bit line (BL); numeral 9 is a memory cell array; numeral 10 is a sense amplifier; numeral 11 is an I/O circuit which controls input and output of data to and from the memory cell array 9; numeral 12 is an internal address generator which generates an address signal for selecting a word line on the basis of the ZRAS signal at the time of self refresh mode; numeral 13 is a self refresh switching circuit which detects that the normal mode has been switched to the self refresh mode on the basis of the ZRAS signal and the ZCAS signal and generates a control signal (ZBBU signal); numeral 14 is a self refresh ring oscillator which generates a ZREFS signal for changing the period of the ZRAS signal on the basis of the ZBBU signal and outputs the ZREFS signal to the RAS buffer 1; and numeral 20 is a Vpp generator which monitors a potential of a Vpp line connected to the word driver 6 for driving the word line and keeps the potential at Vpp. Numeral 21 is a control circuit which generates a ZRAS2 signal and controls the Vpp generator 20 on the basis of the ZBBU signal and the ZRAS signal. The Vpp being a potential for driving the word line shows a higher potential (not lower than Vcc +Vth) than the power source potential Vcc of the DRAM. Reference mark MC indicates a memory cell. At the time of normal mode, the EXTADD signal is inputted to the row address buffer 4, and at the time of self refresh mode, an address signal generated in the internal address generator 12 is inputted to the row address buffer 4. The Vpp being a potential of the Vpp line is supplied to the word driver 6.

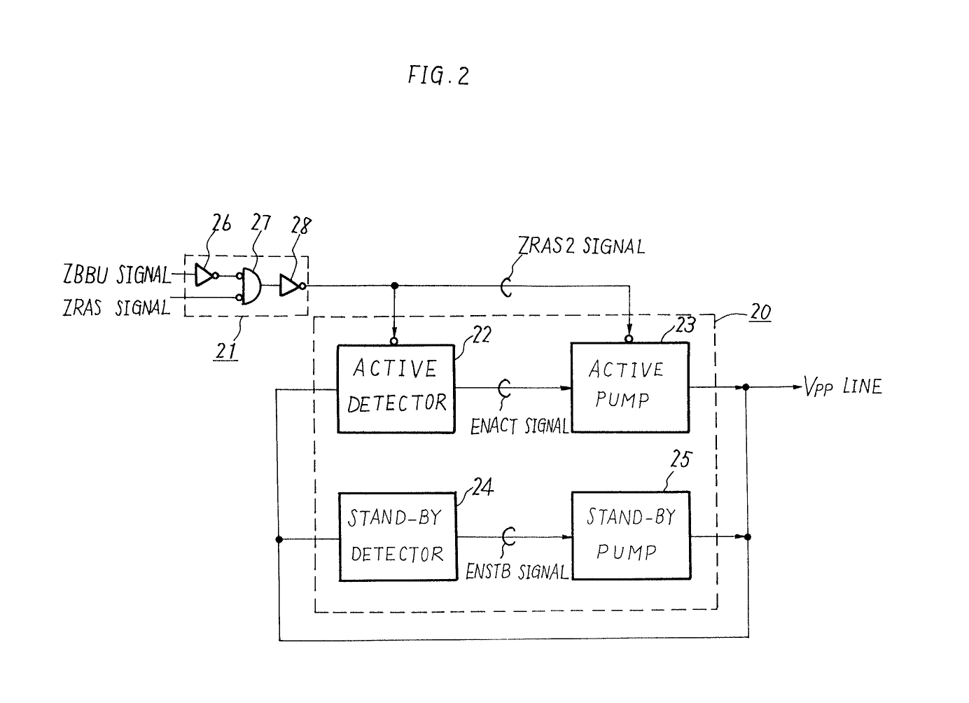

FIG. 2 is a diagram showing an arrangement of the Vpp generator 20 and the control circuit 21 in FIG. 1. In the drawing, reference numeral 22 indicates an active detector, numeral 23 indicates an active pump, numeral 24 is a stand-by detector, and numeral 25 is a stand-by pump. The active detector 22 and the active pump 23 are operated synchronously with the ZRAS2 signal from the control circuit 21. The stand-by detector 24 and the stand-by pump 25 are operated asynchronously with the ZRAS2 signal. The active detector 22 and the stand-by detector 24 monitor the potential of the Vpp line. When a potential of the Vpp line is lower than Vpp, the active pump 23 and the stand-by pump 25 receive results of monitor (ENACT signal, ENSTB signal) respectively from the active detector 22 and the stand-by detector 24, and increase the potential of the Vpp line to Vpp. The active detector 22 monitors the potential of the Vpp line during a certain period after the ZRAS2 signal has been changed from H level to L level, while the stand-by detector 24 monitors the potential of the Vpp line at all times. The control circuit 21 comprises an inverter circuits 26, 28 and a NOR circuit 27, generates the ZRAS2 signal on the basis of the ZBBU signal and the ZRAS signal, and outputs the ZRAS2 signal respectively to the active detector 22 and to the active pump 23. The stand-by pump 25 has a certain pumping capacity (supply capacity of current to the Vpp line) in the same manner as the prior art.

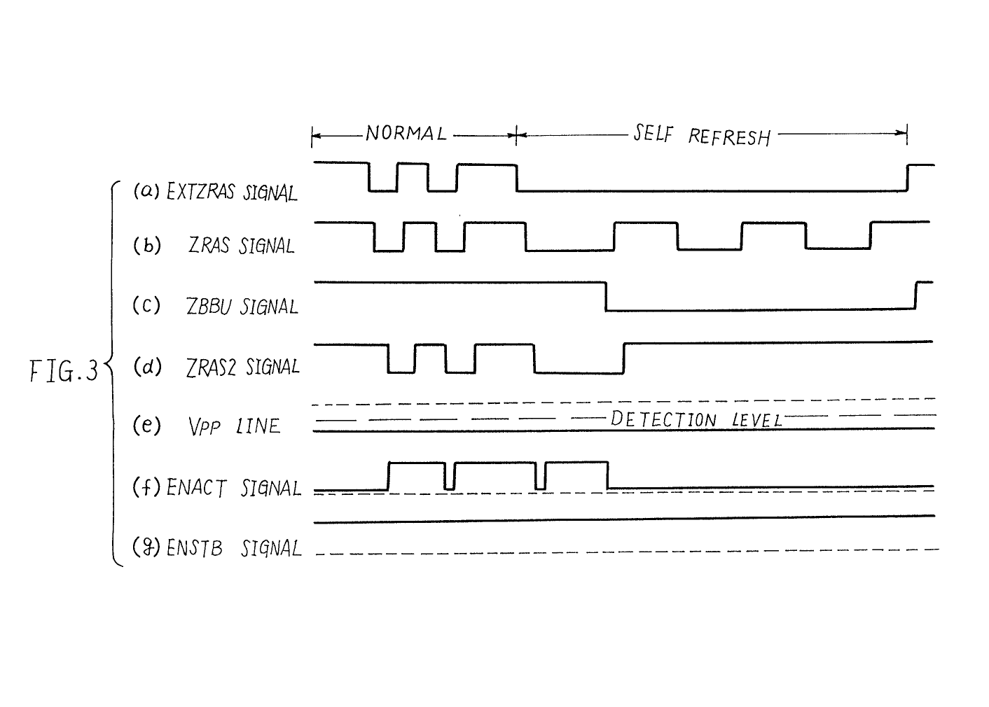

FIG. 3 is a timing chart to explain the operation of the Vpp generator 20 and the control circuit 21. Each circuit has a delay, and the output signal is outputted with a delay from the input signal.

Described first is the time of normal mode (including stand-by time) in which reading and writing operations are performed. In the same manner as in the aforementioned prior art, synchronously with the last transition of the EXTZRAS signal from H level to L level, the ZRAS signal is also changed from H level to L level. The control circuit 21 receives the ZRAS signal from the RAS buffer 1, and considering the ZRAS signal to be the ZRAS2 signal, outputs the ZRAS2 signal to the active detector 22 and to the active pump 23. During a certain period after the ZRAS2 signal has been changed from H level to L level, the active detector 22 monitors the potential of the Vpp line, and when the potential is lower than the detection level, an ENACT signal (H level) is generated and outputted to the active pump 23. The active pump 23 having received the ENACT signal of H level increases the potential of the Vpp line to Vpp. The active detector 22 is not operated (in the non active state) at all times other than a certain period after the ZRAS2 signal has been changed from H level to L level. But, irrespective of the level of the ZRAS2 signal, when the potential of the Vpp line is lower than the detection level, an ENSTB signal (H level) is generated by the stand-by detector 24 monitoring the Vpp line at all times, and the potential of the Vpp line can be increased to Vpp by the stand-by pump 25. At the time of normal mode, the ZBBU signal from the self refresh switching circuit 13 is at H level, and the self refresh ring oscillator 14 is not operated. In conformity with the non active state of the active detector 22, the active pump 23 is not operated.

Then, the self refresh mode is described. The self refresh switching circuit 13 receives the ZRAS signal and the ZCAS signal both changed to L level respectively at the timing CBR, and generates the ZBBU signal of L level to indicate that the operation mode has been set to the self refresh mode. The self refresh oscillator 14 receives the ZBBU signal, generates the ZREFS signal to prolong the period of the ZRAS signal, and outputs the ZREFS signal to the RAS buffer 1. The RAS buffer 1 generates the ZRAS signal having a longer period than that at the time of normal mode on the basis of the ZREFS signal. For example, in the 64 Mbit DRAM, the period of the ZRAS signal is 84 ns to 16 μs at the time of normal mode, while it is about 30 μs at the time of self refresh mode in the same manner as the aforementioned prior art. The internal address generator 12 receives the ZRAS signal, and generates an address signal for selecting a word line for the refreshment. The control circuit 21 receives the ZBBU signal of L level and the ZRAS signal of prolonged period respectively, generates the ZRAS2 signal of H level, and outputs the ZRAS2 signal to the Vpp generator 20.

Including the time of normal mode, when the ZRAS2 signal of H level is inputted to the active detector 22 and the active pump 23, both active detector 22 and active pump 23 are switched to the non active state. Thus, the operation of monitoring the potential of the Vpp line by the active detector 22 and the operation of increasing the potential on the Vpp line by the active pump 23 are not performed.

When switching to the self refresh mode, the ENACT signal is fixed to L level by the ZRAS2 signal and the ZBBU signal. At the time of self refresh mode, the potential of the Vpp line is monitored at all times by the stand-by detector 24 connected to the Vpp line, and when the potential is lower than the detection level, the ENSTB signal (H level) is generated. And the potential of the Vpp line is increased to Vpp by the stand-by pump 25.

Upon completion of the self refresh mode, the EXTZRAS signal is changed from L level to H level, and the ZBBU signal is changed from L level to H level to move to the normal mode. At the time of normal mode, the active detector 22 and the active pump 23 are operated synchronously with the ZRAS2 signal.

At the time of normal mode, the period of the ZRAS signal becomes short, and because read and write operations are performed more frequently, current consumption from the Vpp line is increased and, therefore, a high pumping capacity is required in both active pump 23 and stand-by pump 25. In the 64 Mbit DRAM, at the time of normal mode, the two pumps are operated.

On the other hand, at the time of self refresh mode, the period of the ZRAS signal is set to an order of several tens μs (for example, about 30 μs in the 64 Mbit DRAM) and the current consumption from the Vpp line is small as compared with that at the time of normal mode. Therefore, even if the pumping capacity of the active pump 23 is omitted, the current consumption from the Vpp line can be covered just by the pumping capacity of the stand-by pump 25.

Accordingly, at the time of self refresh mode, the active detector 22 and the active pump 23 are respectively controlled to be in the non active state by the control circuit 21.

In FIG. 3, dot line portions of the Vpp line, the ENACT signal and the ENSTB signal indicate that the potential of the Vpp line is higher than the detection level and that it is not necessary to increase the potential of the Vpp line to Vpp. On the other hand, as described above, solid line portions indicate that the potential of the Vpp line is lower than the detection level and that the increase to Vpp is necessary.

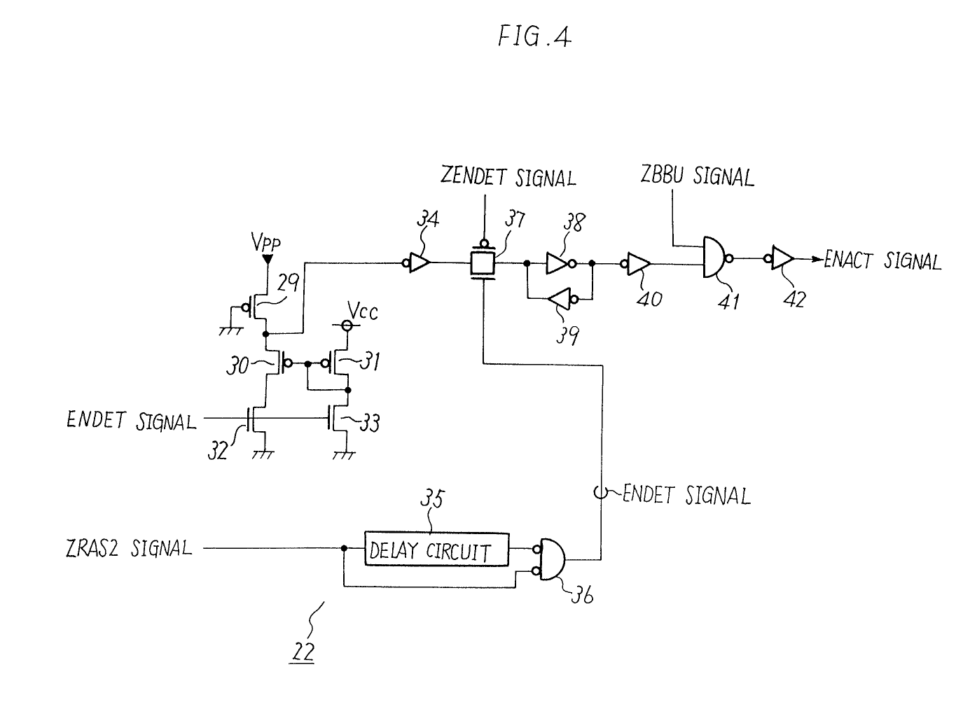

FIG. 4 is a diagram showing an arrangement of the active detector 22 in FIG. 2. In the drawing, reference numerals 29 to 33 indicates transistors, numerals 34, 38, 39, 40 and 42 indicate inverter circuits, numeral 35 is a delay circuit, numeral 36 is a NOR circuit, and numeral 41 is a NAND circuit. Numeral 37 is a transfer gate circuit which controls transmission of signal from the inverter circuit 34 to the inverter circuit 38 on the basis of an ENDET signal from the NOR circuit 36 and the ZENDET signal being an inverted signal of the ENDET signal. The ZENDET signal is a signal generated by inversion of the ENDET signal outputted from the NOR circuit 36 by an inverter circuit (not shown).

Though not shown in FIG. 1 and FIG. 2, the ZBBU signal is inputted to the active detector 22 as shown in FIG. 4.

There is a difference from the conventional active detector 16 in the aspect of providing a NAND circuit 41 for performing a logical operation between the output signal from the inverter circuit 40 and the ZBBU signal, and an inverter circuit 42 for inverting the result of logical operation. It is to be noted that, in the invention, an output signal from this inverter circuit 42 is the ENACT signal. On the other hand, in the prior art, an output from the inverter circuit 40 was the ENACT signal.

Furthermore, in the invention, the ZRAS2 signal is inputted to the delay circuit 35. On the other hand, in the prior art, the signal inputted to the delay circuit was not the ZRAS2 signal but the ZRAS signal.

At the time of normal mode, the active detector 22 monitors the potential of the Vpp line applied to the transistor 29 by controlling the ENDET signal, and generates the ENACT signal according to the result of monitor. In the operation of monitoring the potential of the Vpp line by the active detector 22, when the potential of the Vpp line is higher than the preset detection level, a signal of H level is outputted to the inverter circuit 34. An ENACT signal of L level is generated through the transfer gate circuit 37, the inverter circuits 38, 40, the NAND circuit 41 and the inverter circuit 42. According to the ENACT signal of L level, the active pump 23 does not perform any operation of increasing the potential of the Vpp line. On the other hand, when the potential of the Vpp line is lower than the detection level, a signal of L level is inputted to the inverter circuit 34. An ENACT signal of H level is generated through the transfer gate circuit 37, the inverter circuits 38, 40, the NAND circuit 41 and the inverter circuit 42. According to the ENACT signal of H level, the active pump 23 performs an operation of increasing the potential of the Vpp line to Vpp. The ZBBU signal is at H level.

At the time of normal mode, as the ZBBU signal is at H level, the level of the output signal from the inverter circuit 40 is that of the ENACT signal from the inverter circuit 42.

At the time of self refresh mode, after the ZBBU signal has been changed to L level, the ZRAS2 signal is fixed to H level irrespective of the level of the ZRAS signal. Accordingly, the ENDET signal generated by the ZRAS2 signal is fixed to L level, and the active detector 22 is in the non active state during the self refreshing period. As the ZBBU signal is at L level, the ENACT signal being an activation signal of the active pump 23 is also fixed to L level.

In this manner, at the time of self refresh mode, since the generation of the ENACT signal of H level by the active detector 22 is inhibited, any operation of increasing the potential of the Vpp line is not performed by the active pump 23.

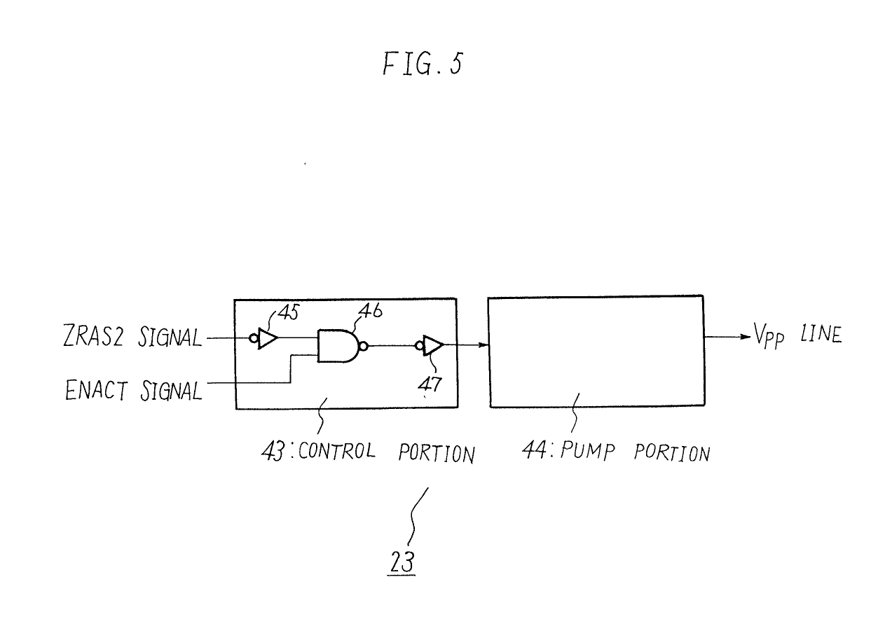

FIG. 5 is a diagram showing an arrangement of the active pump 23. In the drawing, reference numeral 43 indicates a control portion, and numeral 44 indicates a pump portion. The control portion 43 comprises inverter circuits 45, 47 and a NAND circuit 46. The inverter circuit 45 generates an inverted signal of the ZRAS2 signal. The NAND circuit 46 performs a logical operation between the output signal from the inverter circuit 45 and the ENACT signal, and the result is outputted to the inverter circuit 47. The pump portion 44 increases the potential of the Vpp line to Vpp by the output signal of H level from the inverter circuit 47. At the time of self refresh mode, as the ZRAS2 signal is at H level and the ENACT signal is at L level, an output signal of L level is outputted from the inverter circuit 47 to the pump portion 44, and therefore any operation of increasing the potential is not performed by the active pump 23.

In the DRAM according to this embodiment, as the active detector 22 and the active pump 23 unnecessary to operate at the time of self refresh mode are put in the non active state by the control circuit 21, the operation of monitoring the Vpp line by the active detector 22 and the operation of increasing the potential by the active pump 23 are both stopped. Thus, at the time of self refresh mode, any wasteful consumption of current due to each operation of the active detector 22 and the active pump 23 is avoided, and as compared with the prior art, the current consumption of the Vpp generator 20 can be reduced.

In particular, stopping the operation of increasing the potential of the active pump 23 that consumes a large amount of current is an effective reduction in current consumption of the Vpp generator 20.

Further, in the active detector 22 at the time of self refresh mode, since the ENDET signal is fixed to L level by the ZRAS2 signal as described above, the transistors 32, 33 are in the off state. Thus, as compared with the prior art in which the transistors are operated synchronously with the ZRAS signal, the through current generated in the active detector 22 can be restrained.

Furthermore, in the 64 Mbit DRAM, by employing the control circuit 21, the current consumed in the conventional Vpp generator 15 can be reduced by about 50%.

As described so far, in the invention, by providing the control circuit, the operation of increasing the potential of the first pump synchronizing with the RAS signal is stopped under the self refresh mode and, as a result, a DRAM capable of reducing the current consumption of the Vpp generator can be obtained.

Further, by providing the control circuit, the operation of monitoring the detector synchronizing with the RAS signal is also stopped at the time of self refresh mode and, as a result, a dram capable of reducing the current consumption of the Vpp generator can be obtained.

What is claimed is:

1. A dynamic random access memory operable under a normal mode and a self refresh mode comprising: a detector which monitors, synchronously with a RAS signal under said normal mode, a potential of a Vpp line for supplying a potential Vpp for driving a word line; a first pump which increases, synchronously with said RAS signal, the potential of said Vpp line to the potential Vpp for driving the word line, on the basis of a result monitored by said detector; and a second pump which increases, asynchronously with said RAS signal, the potential of said Vpp line to the potential Vpp for driving the word line;
said dynamic random access memory comprising a control circuit which stops an operation of increasing the potential of said Vpp line by said first pump, under said self refresh mode.

2. The dynamic random access memory according to claim 1, wherein said control circuit stops the operation of monitoring the potential of said Vpp line by said detector, at the time of said self refresh mode.

3. The dynamic random access memory according to claim 2, wherein said control circuit is connected to said detector and said first pump, receives a first control signal indicating that said normal mode has been switched to said self refresh mode at the time of said self refresh mode, generates a second control signal for stopping the operation of monitoring by said detector and the operation of increasing the potential by said first pump respectively, and outputs said second control signal to said detector and said first pump.

4. The dynamic random access memory according to claim 3, wherein said control circuit outputs said RAS signal to said detector and said first pump at the time of normal mode.

5. The dynamic random access memory according to claim 4, wherein said detector is inhibited from outputting the result of monitor to said first pump by said first control signal, at the time of said self refresh mode.
